(19) United States
(12) Patent Application Publication
(10) Pub. No.: US 2013/0061912 A1
(43) Pub. Date: Mar. 14, 2013

(54) DIAGONAL MOUNTING BRACKET FOR A PHOTOVOLTAIC MODULE

(71) Applicants: Markus Eberhard Beck, Scotts Valley, CA (US); Raffi Garabedian, Los Altos, CA (US); Pedro Gonzalez, Fremont, CA (US)

(72) Inventors: Markus Eberhard Beck, Scotts Valley, CA (US); Raffi Garabedian, Los Altos, CA (US); Pedro Gonzalez, Fremont, CA (US)

(21) Appl. No.: 13/603,448

(22) Filed: Sep. 5, 2012

Related U.S. Application Data
(60) Provisional application No. 61/532,450, filed on Sep. 8, 2011.

(51) Int. Cl. H01L 31/048; H01L 31/18

(52) U.S. Cl. 136/251; 29/890.033

(57) ABSTRACT

A photovoltaic module has a diagonal mounting bracket for structural attachment of the module to a support structure. The photovoltaic module has a back cover with an outer surface and a diagonal mounting bracket is attached to the back cover and extends along at least a portion of a diagonal of the back cover. A method of forming a photovoltaic module with a diagonal mounting bracket is also described.

### CLAIM OF PRIORITY

This application claims priority under 35 U.S.C. §119(e) to U.S. Provisional Patent Application Ser. No. 61/532,450 filed on Sep. 8, 2011, which is hereby incorporated by reference in its entirety.

### FIELD OF THE INVENTION

Embodiments of the invention relate to the field of photovoltaic (PV) module design, and more particularly to a mounting bracket for a PV module.

### BACKGROUND OF THE INVENTION

A PV module, also known as a solar panel, is a device that converts sunlight into electricity by a process called the “photovoltaic effect.” A PV module includes a plurality of PV cells, also known as solar cells, for example, which may be made using crystalline silicon technology (i.e., monocrystalline, polycrystalline etc.) or thin-film technology (i.e., amorphous silicon (A-Si), copper indium selenide (CIS), copper indium gallium selenide (CIGS), cadmium telluride (CdTe) etc.). The PV cells are typically formed between front and back covers of the PV module.

In thin-film modules, the PV cells can include sequential layers of various materials formed between the front and back covers which protect the PV cells from external hazards. The layers of one thin-film module may include, for example, a barrier layer, a transparent conducting oxide (TCO) layer, a buffer layer, and an active material layer, which can include a window layer and an absorber layer, and a conductive layer, all of which can be deposited on top of the back cover and are formed into PV cells. The barrier layer may protect the active material layer from potential contaminants and the buffer layer can mitigate potential irregularities during the formation of the active material layer, for example. The TCO layer and the conductive layer may serve as electrical contacts. The window layer can allow the penetration of solar energy to the absorber layer, where the optical energy is converted into electrical energy. A front cover, usually formed of glass can then be applied and a pair of internal conductors within the module may extend through a hole in the back cover for connection with external conductors. In many PV modules, a junction box can be provided on the outer surface of the back cover to convey the electricity produced by the PV cells on internal conductors to external electrical components outside of the PV module. The active material layer is formed of one or more layers of semiconductor material such as A-Si, CIGS, CdTe, cadmium sulfide (CdS) or any other suitable light absorbing material.

In the field, PV power generating systems employing PV modules are typically constructed in two steps. First, a mounting system is installed which includes a foundation system such as a series of posts or footings, and a support structure, which can include brackets, tables or rails and clips, and other mechanical support materials. Second, the individual PV modules are mounted on the support structure. PV modules can be arranged into arrays on support structures to achieve a desired level of array voltage and current.

Often a frame is provided around the periphery of a PV module and functions as an attachment platform for mounting the module to the support structure. For example, the frame may be an aluminum extrusion around the periphery of the module that also provides mechanical support for the module. The conventional frame of a PV module may have four connected extruded structural members which may have mounting brackets for mounting the module to the support structure. Thinner PV modules can be frameless and often utilize mounting brackets or clips attached to the peripheral edges of the module to serve as attachment points to the support structure.

The frames, bracket and clips of existing framed and frameless PV modules have drawbacks. For example, the existing PV module frame can account for a large and expensive share (e.g., roughly forty-percent) of the total cost of the materials used to form the elements that mount the PV module to the support structure.

The clips and brackets of frameless modules, while less costly, extend only a limited distance across the rear of the module resulting in limited mounting support and attachment capability.

With innovations in PV modules and systems making PV-generated energy more cost efficient, there is an increasing demand for a PV module mounting structure that provides adequate structural and mechanical support similar to the frame around existing PV modules but at a lower cost and/or provides more mounting support and attachment capability to frameless modules than the multiple brackets or clips presently in use.

### BRIEF DESCRIPTION OF THE DRAWINGS

FIG. 1 illustrates a bottom planar view of a PV module with a diagonal mounting bracket according to a disclosed embodiment;

FIG. 1A illustrates a cross-sectioned view of the PV module of FIG. 1 taken along section A-A;

FIG. 1B illustrates a cross-sectioned view of the PV module of FIG. 1 taken along section A-A;

FIG. 2 illustrates a bottom planar view of a PV module with a diagonal mounting bracket according to a disclosed embodiment;

FIG. 3 illustrates a bottom planar view of a PV module with a diagonal mounting bracket according to a disclosed embodiment;

FIG. 4 illustrates a bottom planar view of a PV module with a diagonal mounting bracket according to a disclosed embodiment; and

FIG. 5 illustrates a bottom planar view of a PV module with a diagonal mounting bracket according to a disclosed embodiment.

### DETAILED DESCRIPTION OF THE INVENTION

In the following detailed description, reference is made to the accompanying drawings which form a part hereof, and which illustrate specific embodiments of the invention. These embodiments are described in sufficient detail to enable those of ordinary skill in the art to make and use them. It is also understood that structural, logical, or procedural changes may be made to the specific embodiments disclosed without departing from the spirit and scope of the invention.

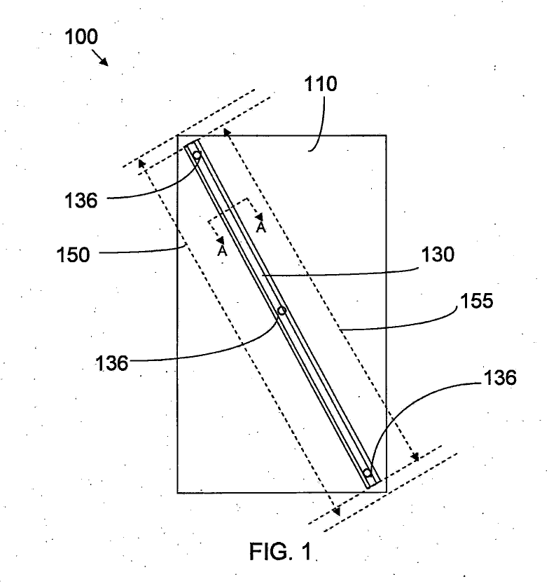

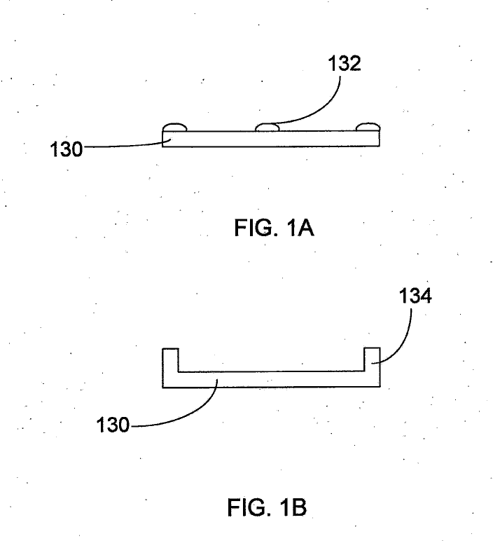

The various embodiments disclosed herein provide structural support for a PV module through the use of a diagonal mounting bracket provided on the back side of a PV module. FIG. 1 illustrates a bottom planar view of a frameless PV module 100 having a front cover (not shown) and a back cover 110 with a plurality of PV cells between them. The module 100 is provided with a diagonal mounting bracket 130 in accordance with a first embodiment. The diagonal mounting bracket 130 extends along at least a portion of a diagonal line of the outer surface of the back cover 110 of the module 100 for structural attachment to a support structure. The diagonal of the back cover 110 has a first length 150 and the diagonal mounting-bracket 130 has a second length 155. The first length 150 may be greater than, or about equal to, the second length 155. Diagonal mounting bracket 130 is directly attached to the module 100 by adhesive, ultrasonic welding or other type of bonding, for example. Diagonal mounting bracket 130 can be formed of aluminum, steel, metal alloy, a polymeric material, or other supporting materials. The diagonal mounting bracket 130 can have a profile with longitudinally extending ribs 132 formed on the outer surface of the bracket 130, as shown in the FIG. 1A, or with longitudinally extending sidewalls 134 formed at opposite side edges of the bracket 130 as shown in the FIG. 1B, for added strength. Bracket 130 may also have spaced fasteners 136, such as bolts or nuts, or engagable grooves to provide attachment points for mounting PV module 100 to a support structure.

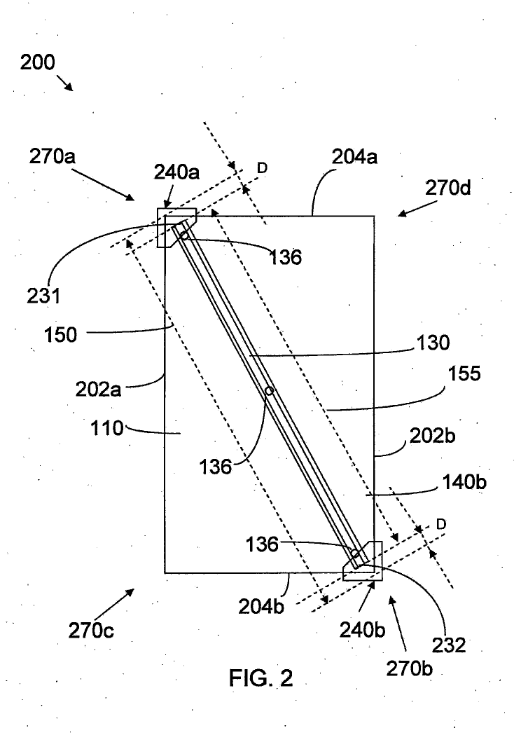

FIG. 2 illustrates a bottom planar view of a frameless PV module 200 with a diagonal mounting bracket 130 in accordance with a second embodiment. The diagonal mounting bracket 130 extends along at least a portion of the diagonal of the outer surface of the back cover 110 and has a first end 231 and a second opposite end 232. Ends 231 and 232 are the primary mounting points for mounting the module 200 to the support structure. Before the bracket 130 is attached to the module 200, corner support clips 240a-b are attached to the front and back 110 covers of the module 200, for example by overmolding, and then ends 231, 232 are fixed to respective corner support clips 240a-b, to further anchor the diagonal mounting bracket 130 to the module 200. The corner support clips 240a-b, which may be formed of the same material as diagonal mounting bracket 130, or may be formed of a different material, extend over and encapsulate the front and back 110 covers at a respective first corner 270a and a second opposite diagonal corner 270b of the module 200. Each corner support clip 240a-b extends along a portion of the respective parallel sides 202a-b and parallel transverse sides 204a-b of the module 200 that define the corners 270a-b. The first 231 and second 232 ends of the diagonal mounting bracket 130 may be fixed to respective corner support clips 240a-b with screws, bolts, by ultrasonic welding, by adhesive or by any other suitable fastening technique.

In FIG. 2, the first 231 and second 232 ends of the diagonal mounting bracket 130 are each spaced from the first 270a and second 270b module corners respectively, a distance D, which can be in the range of about 10 mm to about 30 mm, for example. If parallel elongated sides 202a-b of module 200 measure 1200 mm in length, for example, and parallel transverse sides 204a-b measure 600 mm in length, for example, then the length 155 of the diagonal mounting bracket 130 can measure at least about 1300 mm in length, with distance D equal to about 20 mm. As with the embodiment of FIG. 1, the embodiment of FIG. 2 may also be provided with spaced fasteners 136 and with ribs 132 (FIG. 1A) or raised sidewalls 134 (FIG. 1B).

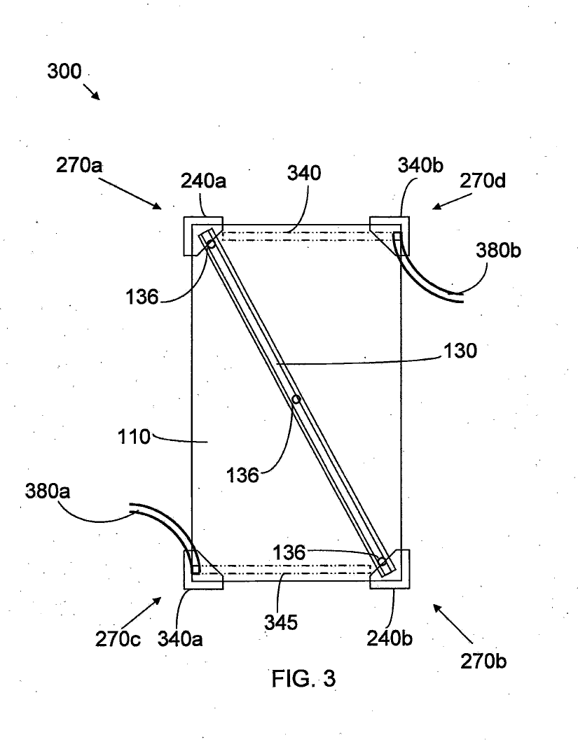

FIG. 3 illustrates a bottom planar view of a frameless PV module 300 with a diagonal mounting bracket in accordance with another embodiment. The FIG. 3 embodiment is similar to that of FIG. 2 with respect to having corner support clips 240a-b and diagonal mounting bracket 130. In the FIG. 3 embodiment, corner support clips 340a-b are attached to the front and back 110 covers of the module 300 at the respective third 270c and fourth opposite diagonal corner 270d of the module 300. In contrast to the prior art, in which junction boxes are provided on the outer surface of the back cover of the module, at least one of corner support clips 340a-b further functions as a PV junction box which conveys the electricity produced by the PV cells on internal conductors 340, 345 to external conductors 380a, 380b and other electrical components outside of the module 300 (e.g. other modules, charge regulators, batteries and inverters). External conductors 380a-b pass into the corner support clips 340a-b and are respectively soldered or otherwise electrically connected to the internal conductors 340, 345 inside the module 300, which may exit from respective side edges of module 300. As a further embodiment, if a junction box is not provided at a corner 270c, 270d, corner support clips 340a-b may be constructed in the same manner as corner support clips 240a-b. As a further embodiment, if a junction box is not provided at a corner 270c, 270d, at least one corner support clip 240a-b may be constructed in the same manner as corner support clips 340a-b and further function as a junction box except that the at least one corner support clip 240a-b would also anchor the diagonal bracket 130 to the module 300.

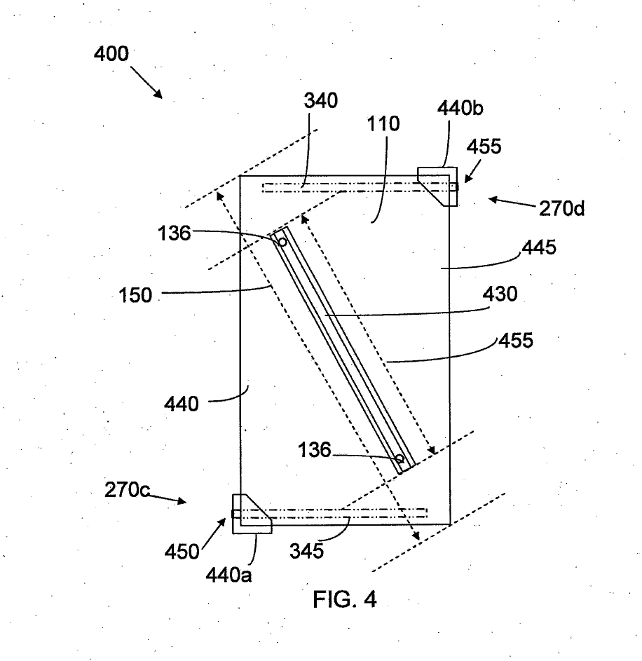

FIG. 4 illustrates a bottom planar view of a frameless PV module 400 with a diagonal mounting bracket 430 in accordance with another embodiment. The diagonal of the back cover 110 has a first length 150 and the diagonal mounting bracket 430 has a second length 455. The second length 455 may be at least about one-third of the first length 150, and may be between about one-third and about two-thirds of the first length 150, for example. Corner support clips 440a-b may provide junction boxes, in the manner disclosed in FIG. 3, at the respective third 270c and fourth 270d corners of the module 400. In this embodiment, the corner support clips 440a-b provide electrical connectors for allowing electrical connections of external conductors to the module 400. For example, at least one of corner support clips 440a-b can include electrical connections formed as at least one edge connector 450, 455, which are electrically connected to and serve as the electrical connectors for internal conductors 340, 345, respectively. Internal conductors 340, 345 may exit a side edge of the module 400 between edge sealed front and back covers or terminate at respective edge connectors 450, 455, as shown in FIG. 4. Examples of electrical edge connectors that may be employed are described in more detail in co-pending application Ser. No. 61/530,660, entitled “Photovoltaic Module With Sealed Perimeter And Method Of Formation,” the disclosure of which is incorporated by reference herein.

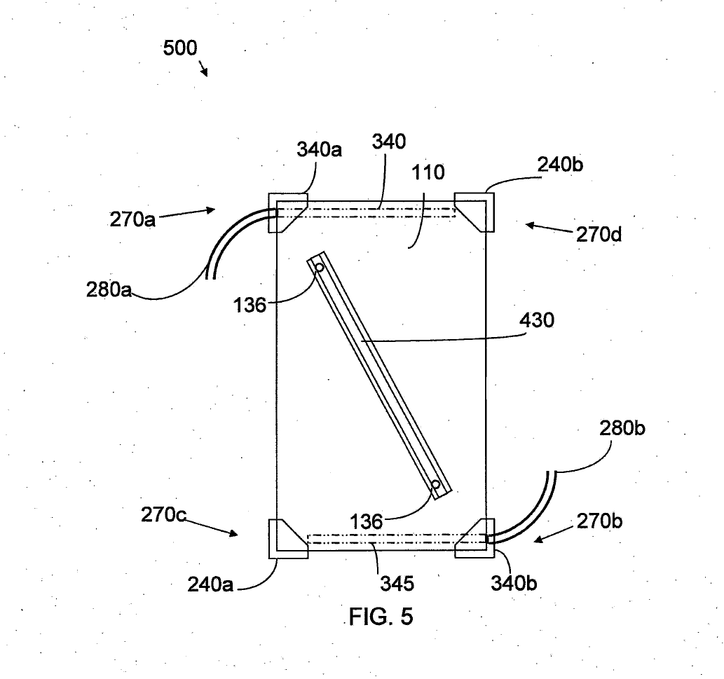

FIG. 5 illustrates a bottom planar view of a frameless PV module 500 with a diagonal mounting bracket in accordance with another embodiment. The diagonal mounting bracket 430 is identical to the one described above in connection with FIG. 4. At least one of corner support clips 340a-b attached at the respective first 270a and second 270b corners of the module 500 may include a junction box, with external conductors 280a-b passing into the junction boxes, as described above with respect to FIG. 3. The other corners 270c-d have corner support clips 240a-b. As an alternative embodiment, if a junction box is not needed at corners 270a-b, then all corners of module 500 may include corner support clips having the construction of corner support clips 240a-b. As a further embodiment, if a junction box is needed and is not provided at a corner 270a, 270b, at least one corner support clip 240a-b may be constructed in the same manner as corner support clips 340a-b and further function as a junction box.

Compared to conventional extruded aluminum module frames, the diagonal mounting bracket 130 of FIGS. 1-3 and 430 of FIGS. 4 and 5 if formed of aluminum, reduces the amount of aluminum extrusion, for example, in a framed PV module by approximately two-thirds, resulting in significant cost savings while offering reliable mechanical support and attachment platform functionality. Compared to the plurality of clips and brackets used in existing frameless PV modules, the diagonal mounting bracket 130, 430 extends a greater distance across the outer surface of the back cover 110, providing for enhanced structural integrity when mounted to a support structure. In addition, each diagonal mounting bracket 130, 430 has spaced fasteners 136 which enable the module to be mounted to a support structure.

The PV modules 100, 200, 300, 400, 500, as described above, may be employed in a mounting system wherein the modules 100, 200, 300, 400, 500, are mounted to a support structure that would be structurally compatible with a diagonal mounting bracket. The support structure can be mounted on the ground, or to other mounting surfaces such as the sides or roof of a building.

While the invention has been described in detail in connection with embodiments known at the time, it should be readily understood that the claimed invention is not limited to the disclosed embodiments. Rather, the embodiments can be modified to incorporate any number of variations, alterations, substitutions, or equivalent arrangements not heretofore described. For example, while the disclosed embodiments of the diagonal mounting bracket are described in connection with a frameless PV module, the disclosed diagonal mounting bracket can be modified to support any dimension and type of PV structures including framed, partially framed, foldable and flexible PV modules. Also, while the various sequential layers of a thin-film PV module are described, this is not limiting. The disclosed embodiments of the diagonal mounting bracket may support a PV module with any suitable sequence of layers between the front and back covers.

What is claimed as new and desired to be protected by Letters Patent of the United States, is:

1. A photovoltaic module comprising:
a front cover and a back cover;
a plurality of photovoltaic cells between the front and back covers; and
a diagonal mounting bracket attached to the back cover and extending along at least a portion of a diagonal of the back cover.

2. The module of claim 1, wherein the diagonal of the back cover has a first length and the diagonal mounting bracket has a second length, wherein the first length is about equal to or greater than the second length.

3. The module of claim 1, wherein the diagonal of the back cover has a first length and the diagonal mounting bracket has a second length, wherein the second length is at least about one-third of the first length.

4. The module of claim 1, wherein the diagonal of the back cover has a first length and the diagonal mounting bracket has a second length, wherein the second length is between about one-third and about two-thirds of the first length.

5. The module of claim 1, wherein the diagonal mounting bracket has longitudinally extending ribs formed on the outer surface of the bracket.

6. The module of claim 1, wherein the diagonal mounting bracket has longitudinally extending sidewalls formed at opposite side edges of the bracket.

7. The module of claim 1, wherein the diagonal mounting bracket has one or more spaced fasteners for fastening the module to a support structure.

8. The module of claim 7, wherein the fasteners are one of bolts and nuts.

9. The module of claim 1, wherein the diagonal mounting bracket comprises at least one of aluminum, steel, metal alloy and a polymeric material.

10. The module of claim 1, further comprising a first and second corner support clip attached to the front and back covers at respective first and second corners of the module provided at opposite ends of a first diagonal of the module, wherein the first and second corner support clips are each connected to respective first and second opposite ends of the diagonal mounting bracket.

11. The module of claim 10, wherein the first and second ends of the diagonal mounting bracket are each spaced a distance in the range of about 10 mm to about 30 mm from the respective first and second corners of the module.

12. The module of claim 10, further comprising a third and a fourth corner support clip attached to the front and back covers at respective third and fourth corners of the module provided at opposite ends of a second diagonal of the module.

13. The module of claim 12, wherein at least one of the first, second, third and fourth corner support clips further comprises a junction box.

14. The module of claim 12, wherein at least one of the first, second, third and fourth corner support clips comprises at least one edge connector for making an electrical connection to said module.

15. The module of claim 3, further comprising a first and second corner support clip attached to the front and back covers at respective first and second corners of the module provided at opposite ends of a first diagonal of the module.

16. The module of claim 15, further comprising a third and a fourth corner support clip attached to the front and back covers at respective third and fourth corners of the module provided at opposite ends of a second diagonal of the module.

17. The module of claim 16, wherein at least one of the first, second, third and fourth corner support clips comprises a junction box.

18. The module of claim 16, wherein at least one of the first, second, third and fourth corner support clips comprises at least one edge connector forming an electrical connection to said module.

19. A method of forming a photovoltaic module comprising the steps of:
providing a front cover and a back cover;
providing a plurality of photovoltaic cells between the front and back covers;
attaching a diagonal mounting bracket to the back cover, the diagonal mounting bracket extending along at least a portion of a diagonal of the back cover between a first and a second corner of the module provided at opposite ends of a first diagonal of the module for structural attachment of the photovoltaic module to a support structure.

20. The method of claim 19, wherein the diagonal of the back cover has a first length and the diagonal mounting bracket has a second length, wherein the first length is about equal to or greater than the second length.

21. The method of claim 19, wherein the diagonal of the back cover has a first length and the diagonal mounting bracket has a second length, wherein the second length is at least about one-third of the first length.

22. The method of claim 19, wherein the diagonal of the back cover has a first length and the diagonal mounting bracket has a second length, wherein the second length is between about one-third and about two-thirds of the first length.

23. The method of claim 19, wherein the diagonal mounting bracket has longitudinally extending ribs formed on the outer surface of the bracket.

24. The method of claim 19, wherein the diagonal mounting bracket has longitudinally extending sidewalls formed at opposite side edges of the bracket.

25. The method of claim 19, wherein the diagonal mounting bracket has one or more spaced fasteners for fastening the module to a support structure.

26. The method of claim 25, wherein the fasteners are one of bolts and nuts.

27. The method of claim 19, wherein the diagonal mounting bracket comprises at least one of aluminum, steel, metal alloy and a polymeric material.

28. The method of claim 19, further comprising the step of attaching a first and a second corner support clip to the front and back covers of the module at respective first and second corners of the module.

29. The method of claim 19, wherein the step of attaching the diagonal mounting bracket comprises using one of adhesive and ultrasonic welding.

30. The method of claim 28, wherein the first and second opposite ends of the diagonal mounting bracket are each spaced a distance in the range of about 10 mm to about 30 mm from the respective first and second corners of the module.

31. The method of claim 28, further comprising the step of attaching a third and a fourth corner support clip to the front and back covers at respective third and fourth corners of the module provided at opposite ends of a second diagonal of the module.

32. The method of claim 31, wherein at least one of the first, second, third and fourth corner support clips further comprises a junction box.

33. The method of claim 31, wherein at least one of the first, second, third and fourth corner support clips comprises at least one edge connector for making an electrical connection to said module.

34. The method of claim 21, further comprising the step of attaching a first and second corner support clip to the front and back covers at respective first and second corners of the module.

35. The method of claim 34, further comprising the step of attaching a third and a fourth corner support clip to the front and back covers at respective third and fourth corners of the module provided at opposite ends of a second diagonal of the module.

36. The method of claim 35, wherein at least one of the first, second, third and fourth corner support clips comprises a junction box.

37. The method of claim 35, wherein at least one of the first, second, third and fourth corner support clips comprises at least one edge connector forming an electrical connection to said module.
